(19) United States
(12) Patent Application Publication
(10) Pub. No.: US 2006/0188646 A1
(43) Pub. Date: Aug. 24, 2006

(54) System and method for detecting remaining amount of precursor in vessel during CVD process

(76) Inventors: Ju Young Yun, Daejeon (KR); Kwang Hwa Chung, Daejeon (KR); Bong Young Ahn, Daejeon (KR); Yong Hyeon Shin, Daejeon (KR)

Correspondence Address: VIDAS, ARRETT & STEINKRAUS, P.A., 6109 BLUE CIRCLE DRIVE, SUITE 2000, MINNETONKA, MN, 55343-9185, US

(21) Appl. No.: 11/063,313

(22) Filed: Feb. 21, 2005

(51) Int. Cl. C23C 16/52; C23C 16/00; B05C 11/00

(52) U.S. Cl. 427/8; 427/248.1; 118/715; 118/712

(57) ABSTRACT

The present invention relates to a system and method for detecting the remaining amount of a precursor in a vessel during a chemical vapor deposition (CVD) process. More particularly, the inventive system and method allow accurate measurement of the liquid level of the precursor remaining in the vessel during the CVD process by analyzing signals obtained by transmitting/receiving an ultrasonic wave. Thus, according to the present invention, the liquid level of the precursor can be measured in real time by means of an ultrasonic level sensor, thus preventing damages caused by the exhaustion of the precursor, resulting in a remarkable reduction in inferior products. Also, based on the above measurement results, the optimal replacement time of the precursor can be determined, thus extending the use period of the precursor to the maximum.

### BACKGROUND OF THE INVENTION

1. Field of the Invention

The present invention relates to a system and method for detecting the remaining amount of a precursor in a vessel during a chemical vapor deposition (CVD) process. More particularly, the inventive system and method enables accurate measurement of the liquid level of the precursor remaining in the vessel during the CVD process by analyzing signals obtained by transmitting/receiving an ultrasonic wave.

2. Background of the Related Art

In general coating technology and semiconductor processing, the importance of CVD processes is gradually increased. Particularly, due to the limitation of the prior physical vapor deposition processes caused by a reduction in linewidth, interests in CVD processes using a chemical precursor having excellent step coverage characteristics are increased. In addition to the CVD processes, atomic layer deposition processes with more excellent step coverage characteristics are frequently used.

Generally, in the CVD process, a liquid chemical precursor in a vessel is vaporized by various methods, and the vaporized chemical precursor is delivered into a reaction chamber in which it is then deposited onto a substrate.

Particularly in semiconductor lines, etc., at least several tens of wafers are continuously deposited with a chemical precursor in the reaction chamber, during which, if the chemical precursor is exhausted, serious problems will occur. Recently, in the semiconductor processing field, the research and development are extended to metal-organic chemical vapor deposition (MOCVD) processes using a organic metal compound as a precursor.

Thus, a post-determination process of checking the state of the chemical precursor deposited on the wafer, after the vapor deposition process, is conducted, and there are no detection structure which allows real-time measurement of the remaining amount of the precursor during the vapor deposition processes.

In an attempt to solve this problem, a method is proposed which calculates the number of deposited wafers to replace the precursor before consumption in a vessel. However, this method has low effectiveness since it is difficult to acquire accurate date on the consumption amount of the precursor per use time because of the characteristics of the precursor.

Also, buoyancy sensors are generally used, but the sensors inserted into the precursor cause a problem, such as corrosion or contamination. In addition, they cause gas leakage due to a complicated structure and make it impossible to secure safety in toxic CVD processes.

Furthermore, there is no suitable method to detect and determine the optimal replacement time of the precursor. Thus, when the precursor is replaced even thought a significant amount of the precursor remaining amount in the vessel, its economic loss will be significant.

### SUMMARY OF THE INVENTION

Accordingly, the present invention has been made to solve the above-described problems occurring in the prior art, and it is a first object of the present invention to provide a system and method for detecting the remaining amount of a precursor in a vessel during a CVD process, which allow real-time measurement of the liquid level of the precursor by means of a ultrasonic level detector disposed on the bottom of the vessel containing the precursor, so as to prevent damages caused by the exhaustion of the precursor, resulting in a remarkable reduction in inferior products.

A second object of the present invention is to provide a system and method for detecting the remaining amount of a precursor in a vessel during a CVD process, which allow the optimal replacement time of the precursor to be determined based on the results of said real-time measurement, thus extending the use period of the precursor to the maximum.

A third object of the present invention is to provide a system and method for detecting the remaining amount of a precursor in a vessel in a CVD process, which can eliminate corrosion or contamination, or the risk of gas leakage caused by a complicated structure, by means of a liquid level detector disposed on the bottom of the precursor storage vessel, and also allow safety to be secured even in a toxic CVD process.

To achieve these objects, the present invention provides a system for detecting the remaining amount of a precursor in a vessel during a CVD process, the system comprising: a bombe containing carrier gas; a bombe for containing carrier gas; a first pipe whose one end is connected to the bombe such that the carrier gas can flow through the first pipe; a vessel for containing a liquid precursor, to which the other end of the first pipe is so connected as to be submerged in the precursor such that the precursor can be bubbled and vaporized by the carrier gas; a second pipe whose one end is connected to the vessel in such a way as to be placed above the liquid surface of the precursor such that the precursor and the carrier gas can be transported through the second pipe; a reactor to which the other end of the second pipe is connected and in which a chemical vapor deposition process is performed on a wafer disposed therein with the precursor; a liquid level detector disposed on the bottom of the vessel such that it transmits an ultrasonic wave and receives the ultrasonic wave reflected from the level surface of the precursor; an A/D converter connected to the liquid level detector for converting the analog ultrasonic signals to digital signals; and a discrimination unit connected to the A/D converter for discriminating whether or not the liquid level of the precursor is relatively low, based on the transmitted/received data.

In the inventive system, the liquid level detector preferably comprises an ultrasonic sensor attached to the bottom of the vessel for transmitting a pulsed ultrasonic wave to the liquid surface of the precursor and sensing the ultrasonic wave reflected from the liquid surface; and a pulse receiver electrically connected to the ultrasonic sensor for receiving the sensed ultrasonic wave and detecting an analog signal on each of the transmitted/received ultrasonic waves.

Preferably, the inventive system further comprises an output means connected to the discrimination unit for alarming if the liquid level of the precursor is lower than the reference liquid level.

The alarm output means is preferably an alarm generator for generating an alarm sound, or an output means which is so set that it outputs not only an alarm sound but also a warning indication as an image through a computer monitor.

Preferably, the vessel is connected to a separate tank for containing a precursor by a control unit, in which the control unit is connected to the discrimination unit such that the amount of the precursor in the vessel can be maintained constant.

In another aspect, the present invention provides a method for detecting the remaining amount of a precursor in a vessel during a CVD process, the method comprising the steps of: bubbling and vaporizing a liquid precursor (S1000); chemically vapor-depositing the precursor on a wafer (S2000); transmitting a pulsed ultrasonic wave from an ultrasonic sensor attached on the vessel bottom to the liquid surface of the precursor (S3000); sensing the ultrasonic wave reflected from the liquid surface (S4000); receiving the reflected ultrasonic wave and detecting an analog signal for each of the transmitted/received ultrasonic waves (S5000); converting the analog signals to digital signals (S6000); calculating the liquid level of the precursor, based on the digital data for the generation time interval between the transmitted/received signals, and comparing the calculated liquid level with the reference liquid level data preset for the precursor, so as to discriminate whether or not the liquid level of the relevant precursor is relatively low (S7000); and generating an alarm sound if the liquid level of the relevant precursor is lower than the reference liquid level (S8000).

Preferably, the inventive method further comprises the step of, if the liquid level of the relevant precursor is lower than the reference liquid level, supplying an additional precursor into the vessel so as to maintain the liquid level of the precursor constant.

### BRIEF DESCRIPTION OF THE DRAWINGS

The above and other objects, features and advantages of the present invention will be apparent from the following detailed description of the preferred embodiments of the invention in conjunction with the accompanying drawings, in which:

FIG. 1 shows the construction of the inventive system for detecting the remaining amount of a precursor in a vessel;

FIG. 2 is a flow chart showing the inventive method for detecting the remaining amount of a precursor in a vessel during a CVD process;

FIG. 3 is a graph showing measurement results obtained by an oscilloscope connected to the inventive liquid level detector;

FIG. 4 is a graph showing the measurement results of round-trip time at different liquid levels of a precursor; and

FIG. 5 is a graph showing the comparison of the results of FIG. 4 with actual values.

### DETAILED DESCRIPTION OF THE PREFERRED EMBODIMENT

Hereinafter, the inventive system and method for detecting the remaining amount of a precursor in a vessel during a CVD process will be described with reference to the accompanying drawings.

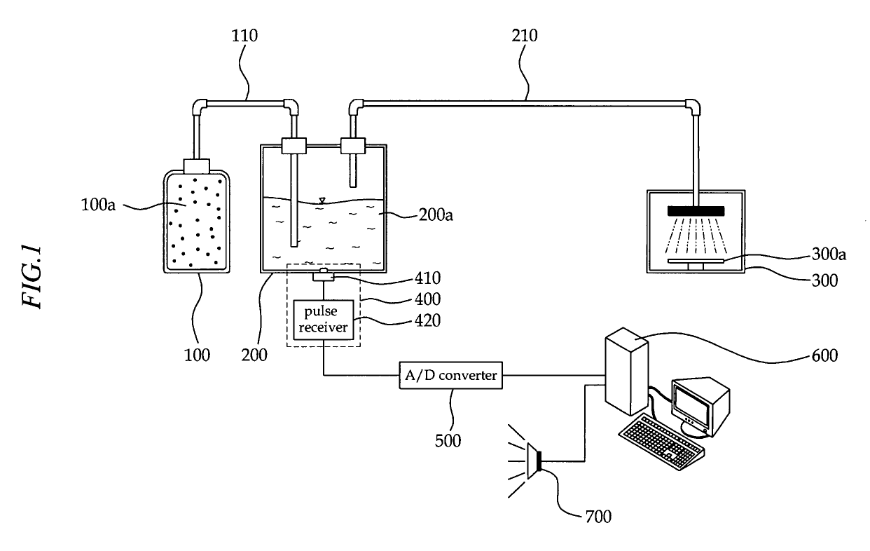

FIG. 1 shows the construction of the inventive system for detecting the remaining amount of a precursor in a vessel. As shown in FIG. 1, in a process of chemically vapor-depositing a precursor 200a on a wafer 300a, the inventive system has a structure allowing the amount of a precursor to be measured by means of an ultrasonic sensor 410 so attached that it continuously measures the liquid level of the precursor 200a, which is lowered as the precursor 200a is deposited on the wafer 300a. If the measurement results indicate that the liquid level of the precursor 200a is lower than the reference liquid level, an alarm sound or a warning image will be outputted so as to induce the interruption of the deposition process.

For this purpose, the inventive detection system comprises a bombe 100 for containing a carrier gas 100a; a first pipe 110 whose one end is connected to the bombe 100; a vessel 200 for containing the liquid precursor 200a, to which the other end of the first pipe 110 is connected so as to be submerged into the precursor 200a; a second pipe 210 whose one end is connected to the vessel 200 in such a manner that it is placed above the liquid surface of the precursor 200a; and a reactor 300 for containing the wafer 300a, to which the other end of the second pipe is connected. Also, the inventive system comprises a liquid level sensor 400 disposed on the bottom of the vessel 200 such that it transmits and receives an ultrasonic wave; an A/D converter 500 for converting the received ultrasonic signal to a digital signal; and a computer 600 for calculating the liquid level of the precursor 200a, based on the digital signal, and discriminating that the calculated liquid level is higher or lower than the reference liquid level. To the computers 600, an alarm generator 700 may be connected which generates an alarm sound if the discrimination result indicates that the liquid level of the precursor 200a is lower than the reference liquid level.

The bombe 100 contains a high-pressure carrier gas 100a and is connected to the vessel 200 by the first pipe 110. One end of the first pipe 110 is connected to the bombe 100 and the other end is inserted into the vessel 200 such that it is submerged into the liquid precursor 200a. Accordingly, the carrier gas 100a will be injected into the precursor 200a by the first pipe 100, thus bubbling the precursor 200a.

To the vessel 200, the second pipe 210 is connected. Namely, one end of the second pipe 210 is inserted into the vessel 200 such that it is placed above the liquid level of the precursor 200a. The precursor 200a which has been vaporized by the above-described bubbling flows out through the second pipe 210.

The other end of the second pipe 210 is connected to the reactor 300. Thus, the vaporized precursor 200a flows into the reactor 300 in which it then performs chemical vapor deposition on the wafer 300 included in the reactor 300.

As this chemical vapor deposition process is progressed, the amount of the precursor 200a contained in the vessel 200 gradually reduces, and from any point of time, reaches a level at which it can no longer perform the deposition process. For this reason, in order to minimize the generation of inferior products caused by lack of the precursor 200a and to determine the optimal replacement time of the precursor 200a, it is necessary that the remaining amount (i.e., liquid level) of the precursor 200a is determined in real time.

In the construction of the inventive detection system including the liquid level detector 400, an ultrasonic wave is transmitted from the bottom of the precursor 200a to the liquid surface of the precursor 200a, and the ultrasonic wave returned by reflection from the liquid surface is received to determine the liquid level of the precursor 200a, which now remains. Then, the determined liquid level is compared with the preset reference liquid level, so as to determine whether the precursor 200a is lacked or not.

More specifically, the liquid level detector 400 consists of an ultrasonic sensor 410 and a pulse receiver 420. The ultrasonic sensor 410 attached to the bottom of the vessel 200 emits an ultrasonic wave to the liquid surface of the precursor 200 and senses the ultrasonic wave reflected from the liquid surface. The pulse receiver 420 receives the sensed ultrasonic signal and detects an analog signal for each of the transmitted/received ultrasonic waves.

These analog signals are converted to digital signals by the A/D converter, for discrimination by the computer 600. At this time, the computer 600 calculates the liquid level of the precursor 200a, based on the digital data for the generation time interval between the transmitted/received ultrasonic waves, and compares the calculated liquid level with the reference liquid level preset for the precursor 200a, so as to discriminate if the relevant liquid level of the precursor 200a is relatively low.

As used herein, the reference liquid level is the reference point showing that the precursor 200a needs to be replaced, below which the precursor 200a can no longer perform the deposition process.

If the discrimination result indicates that the liquid level of the relevant precursor 200a is lower than the reference liquid level, the computer 600 will transmit a signal to an alarm generator 700, an alarm output means electrically connected thereto, thus generating an alarm sound.

The alarm output means may also be so set that it outputs not only the alarm sound but also a warning indication as an image through a monitor on the computer 600.

In another embodiment, a tank (not shown) containing a liquid precursor is connected to the vessel 200 together with a control unit (not shown). The control unit is connected also to the computer. This allows the amount of the precursor 200a in the vessel 200 to be maintained constant at a preset liquid level.

If the result of computer discrimination showing the analysis of the data from the liquid level detector 400 indicates that the relevant liquid level of the precursor 200a is lower than the preset liquid level, the computer 600 causes the liquid precursor in the tank (not shown) to flow into the vessel 200 by the control unit (not shown). This allows the amount of the precursor 200a in the vessel 200 to be maintained constant at the preset liquid level at which the precursor 200a can continuously perform the deposition process.

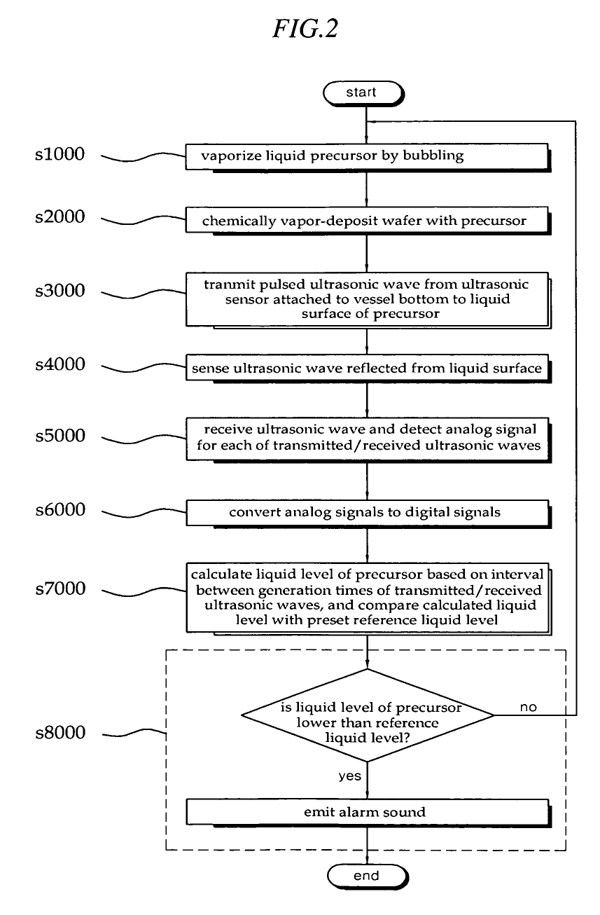

FIG. 2 is a flow chart showing the inventive method for detecting the remaining amount of the precursor 200a in the vessel 200 in a chemical vapor deposition. As shown in FIG. 2, the carrier gas 100a in the bombe 100 bubbles and vaporizes the liquid precursor 200a contained in the vessel 200 so as to deliver the vaporized precursor into the reactor 300 (S1000).

The precursor 200a delivered into the reactor 300 is chemically deposited on the wafer 300a included in the reactor 300 (S2000).

When these steps are continuously performed, the ultrasonic sensor 410 attached to the bottom of the vessel 200 transmits a pulsed ultrasonic wave toward the liquid surface of the precursor 200a in order to measure the liquid level of the precursor 200a in the vessel 200 (S3000) . The transmitted ultrasonic wave is reflected from the liquid surface of the precursor 200a and returned again to the ultrasonic sensor 410. The returned ultrasonic wave is sensed by the ultrasonic sensor 410 (S4000) and received by a pulse receiver 420 which is electrically connected to the sensor (410) (S5000).

The received ultrasonic signal is a pulsed analog signal. Thus, for analysis by the computer 600, the analog signal is converted to a digital signal by the A/D converter 500 (S6000).

In the computer 600, the data of the digital signal is analyzed to calculate the liquid level of the precursor 200a. The principle of the calculation is as follows. Distance is calculated by multiplying the velocity by elapsed time. Thus, the liquid level of the precursor 200a can be measured by multiplying the velocity of an ultrasonic wave transmitted to the liquid surface of the precursor 200a by the time to reach the liquid surface, which is determined by the time interval between the generation time of the transmitted ultrasonic wave and the generation time of the received ultrasonic wave.

The liquid level of the precursor 200a determined by this calculation result is compared with the preset reference liquid level (S7000).

At this time, if the liquid level of the precursor 200a is lower than the reference liquid level, indicating that the precursor 200a can no longer perform the deposition process, the computer 600 will output a signal to generate an alarm sound. This signal is inputted to the alarm generator 700 electrically connected to the computer 600, thus generating the alarm sound (S8000)

Although the alarm generator 700 of generating the sound as the output means for the warning condition has been illustrated in the present invention, the present invention is not limited to this alarm generator and may also use other means capable of giving users a warning, for example, a monitor outputting a warning indication as an image, or a lamp emitting light with a certain color.

In another embodiment, the computer 600 compares the liquid level of the precursor 200a determined by the above calculation result with the preset liquid level.

If the comparison result indicates that the liquid level of the relevant precursor is lower than the preset liquid level, the computer 600 causes the precursor to flow from the tank into the vessel 200 by the control unit. Thus, the liquid level of the precursor 200a in the vessel 200 is maintained constant, and the chemical vapor deposition is continuously progressed.

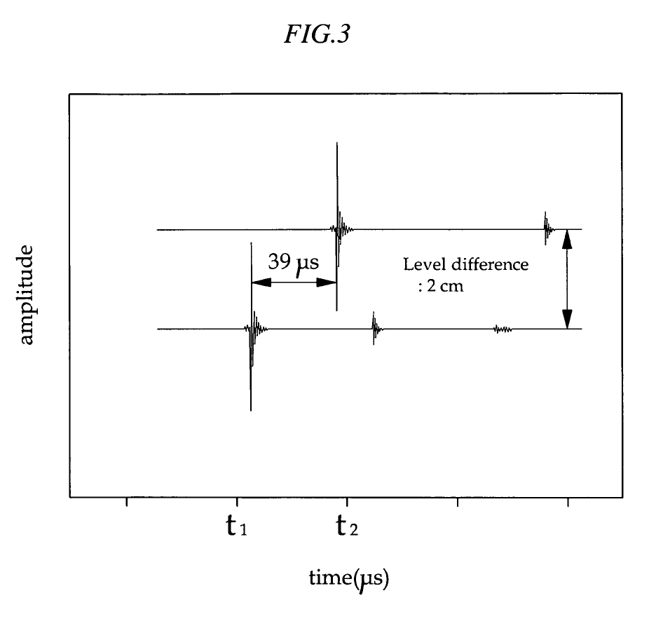

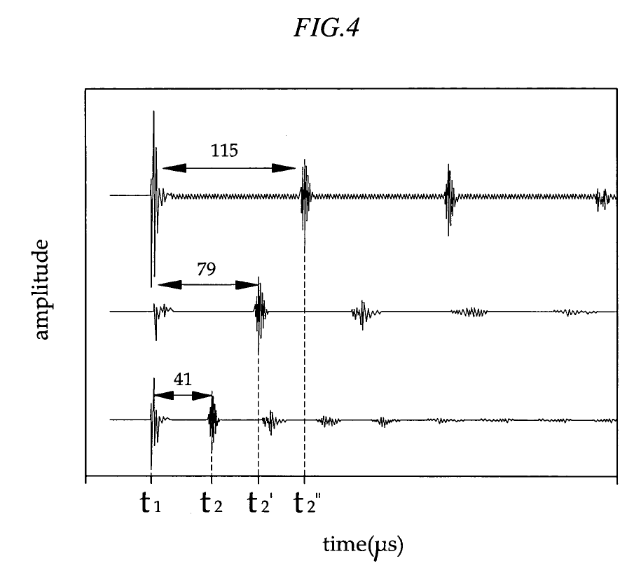

The procedure of calculating the liquid level of the fluid by the waveshape of the ultrasonic wave received by the pulse receiver 420 of the liquid level sensor 400 in the inventive detection system will be described with reference to FIGS. 3 to 5. FIG. 3 is a graph showing measurement results obtained by an oscilloscope connected to the inventive liquid level detector, and FIG. 4 is a graph showing the measurement results of round-trip time at different liquid levels of the precursor. As shown in FIGS. 3 and 4, the X-axis denotes time in μs and the Y-axis denotes amplitude.

The magnitude of the emitted pulse is 5 MHz, and the used precursor is tetrakis-ethoxy-silane (TEOS) which is used mainly in a CVD SiO₂ process.

The liquid level (d) of the liquid precursor in the vessel is calculated by the following equation (1):
d=r([½]t) (1)

wherein r is the ultrasonic pulse velocity in the relevant liquid precursor, and t is the round-trip time of a pulse to the liquid surface.

Using the above equation (1), the ultrasonic pulse velocity in TEOS is first determined. When the round-trip time of the ultrasonic pulse is measured at a liquid level set to 2 cm, the time interval from the transmission time of the ultrasonic wave (t₁) to the pulse generation time of the ultrasonic wave reflected from the liquid surface of TEOS (t₂) is about 39 μs as shown in FIG. 3. The substitution of the equation (1) with the measurement result indicates that the ultrasonic pulse velocity (r) in TEOS is about 1024 m/sec.

As shown in FIG. 4, the round trip times measured at different liquid levels of 2 cm, 4 cm and 6 cm are 41 sec, 79 sec and 115 sec, respectively. The liquid levels calculated by substituting the above equation with the measured pulse velocity and the measured round-trip times (41 sec, 79 sec and 115 sec) are about 2.1 cm, 3.8 cm and 5.9 cm, respectively.

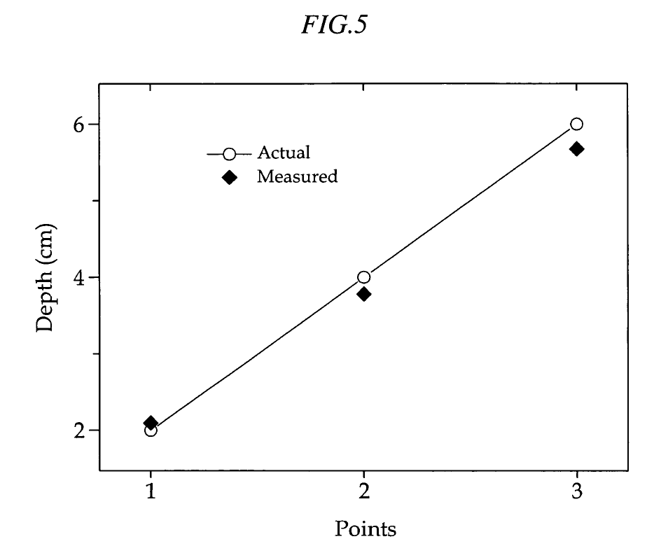

FIG. 5 is a graph showing the comparison of the measured values of FIG. 4 with actual values. In FIG. 5, the X-axis denotes relative points in serial number, and the Y-axis denotes the depth (liquid level) of the precursor in cm. As can be seen in FIG. 5, the actual values and measured values for the liquid surface levels of the precursor, which correspond to measured round-trip times of point 1 (41 sec), point 2 (79 sec) and point 3 (115 sec), are substantially the same. This suggests that the ultrasonic sensor system can be used as a monitoring device for TEOS, a precursor for a semiconductor.

According to the inventive detection system and method using this liquid level detector, any liquid level of the precursor 200a can be measured by the above-described principle, thus determining the optimal replacement time of the precursor 200a.

In the inventive system and method for detecting the remaining amount of the precursor 200a in the vessel 200 during the chemical vapor deposition process, the precursor 200a is not limited to any specific precursor. Since measuring the liquid level of the precursor 200a by the ultrasonic wave can be applied to all precursors, the inventive detection system and method can be applied to all precursors used in chemical vapor deposition, including inorganic, organic and organometal compounds.

Also, the present invention can be used in not only chemical vapor deposition processes but also other vapor deposition processes using the liquid precursor 200a, for example atomic layer deposition processes and semiconductor deposition processes.

In addition, in the present invention, there has been illustrated the system where the precursor 200a contained in the vessel 200 is bubbled by the carrier gas stored in the bombe 100 so that it is delivered into the reactor 300. However, the present invention is not limited to the illustrated system, and it is also possible to inject the precursor 200a into the reactor 300 by an injection process.

As described above, according to the inventive system and method for detecting the remaining amount of the precursor in the vessel during the chemical vapor deposition process, the liquid level of the precursor during the chemical vapor deposition process in the semiconductor processing can be measured in real time. This can prevent damages caused by the exhaustion of the precursor, resulting in a remarkable reduction in inferior products.

Also, based on the above measurement results, the optimal replacement time of the precursor can be determined, thus extending the use period of the precursor to the maximum.

In addition, based on the above measurement results, the amount of the precursor in the vessel can be maintained constant, thus preventing damages caused by the exhaustion of the precursor.

Although a preferred embodiment of the present invention has been described for illustrative purposes, those skilled in the art will appreciate that various modifications, additions and substitutions are possible, without departing from the scope and spirit of the invention as disclosed in the accompanying claims.

What is claimed is:

1. A system for detecting the remaining amount of a precursor in a vessel during a CVD process, the system comprising:
a bombe for containing carrier gas;
a first pipe whose one end is connected to the bombe such that the carrier gas can flow through the first pipe;
a vessel for containing a liquid precursor, to which the other end of the first pipe is so connected as to be submerged in the precursor such that the precursor can be bubbled and vaporized by the carrier gas;
a second pipe whose one end is connected to the vessel in such a way as to be placed above the liquid surface of the precursor such that the precursor and the carrier gas can be transported through the second pipe;
a reactor to which the other end of the second pipe is connected and in which a chemical vapor deposition process is performed on a wafer disposed therein with the precursor;
a liquid level detector disposed on the bottom of the vessel such that it transmits an ultrasonic wave and receives the ultrasonic wave reflected from the level surface of the precursor;
an A/D converter connected to the liquid level detector for converting the analog ultrasonic signals to digital signals; and
a discrimination unit connected to the A/D converter for discriminating whether or not the liquid level of the precursor is relatively low, based on the transmitted/received data.

2. The system of claim 1, wherein the liquid level detector preferably comprises:
an ultrasonic sensor attached to the bottom of the vessel for transmitting a pulsed ultrasonic wave to the liquid surface of the precursor and sensing the ultrasonic wave reflected from the liquid surface; and
a pulse receiver electrically connected to the ultrasonic sensor for receiving the sensed ultrasonic wave and detecting an analog signal on each of the transmitted/received ultrasonic waves.

3. The system of claim 1, which further comprises an output means connected to the discrimination unit for alarming if the liquid level of the precursor is lower than the reference liquid level.

4. The system of claim 3, wherein the alarm output means is an alarm generator for generating an alarm sound.

5. The system of claim 3, wherein the alarm output means is so set that it outputs not only an alarm sound but also a warning indication as an image through a computer monitor.

6. The system of claim 1, wherein the vessel is connected to a separate tank for containing a precursor by a control unit, in which the control unit is connected to the discrimination unit such that the amount of the precursor in the vessel can be maintained constant.

7. A method for detecting the remaining amount of a precursor in a vessel during a CVD process, the method comprising the steps of:
bubbling and vaporizing a liquid precursor (S1000);
chemically vapor-depositing the precursor on a wafer (S2000);
transmitting a pulsed ultrasonic wave from an ultrasonic sensor attached on the vessel bottom to the liquid surface of the precursor (S3000);
sensing the ultrasonic wave reflected from the liquid surface (S4000);
receiving the reflected ultrasonic wave and detecting an analog signal for each of the transmitted/received ultrasonic waves (S5000);
converting the analog signals to digital signals (S6000);
calculating the liquid level of the precursor, based on the digital data for the generation time interval between the transmitted/received signals, and comparing the calculated liquid level with the reference liquid level data preset for the precursor, so as to discriminate whether or not the liquid level of the relevant precursor is relatively low (S7000); and
generating an alarm sound if the liquid level of the relevant precursor is lower than the reference liquid level (S8000).

8. The method of claim 7, wherein, if the liquid level of the precursor 200a is higher than the reference liquid level, the vapor deposition process on the wafer is continuously performed, and the ultrasonic sensor 410 transmits an additional ultrasonic wave to the liquid surface of the precursor 200a, and the steps up to the step of the discrimination by the computer 600 are repeatedly performed.

9. The method of claim 7, which further comprises the step of, if the liquid level of the relevant precursor is lower than the reference liquid level, supplying an additional precursor into the vessel so as to maintain the liquid level of the precursor constant (S8000-1).
